(19) United States
(12) Patent Application Publication
(10) Pub. No.: US 2020/0335463 A1
(43) Pub. Date: Oct. 22, 2020

(54) ELECTRICAL BINDING STRUCTURE AND METHOD OF FORMING THE SAME

(71) Applicant: MIKRO MESA TECHNOLOGY CO., LTD., Apia (WS)

(72) Inventor: Li-Yi CHEN, Tainan City (TW)

(21) Appl. No.: 16/390,017

(22) Filed: Apr. 22, 2019

(51) Int. Cl. H01L 23/00

(52) U.S. Cl. CPC H01L 24/08; H01L 24/03; H01L 24/32

(57) ABSTRACT

An electrical binding structure is provided, which includes a substrate, a contact pad set, and a combination of a micro device and an electrode set. The contact pad set is on the substrate in which the contact pad set includes at least one contact pad, and the at least one contact pad is conductive. The combination is on the contact pad set. Opposite sides of the electrode set is respectively in contact with the micro device and the contact pad set. A vertical projection of a contact periphery between the contact pad set and the electrode set on the substrate is longer than a vertical projection of an outer periphery of the micro device on the substrate in which said vertical projection of the contact periphery on the substrate is enclosed by said vertical projection of the outer periphery on the substrate.

### BACKGROUND

### Field of Invention

The present disclosure relates to an electrical binding structure and a method of forming an electrical binding structure.

### Description of Related Art

The statements in this section merely provide background information related to the present disclosure and do not necessarily constitute prior art.

Traditional technologies for transferring of devices include transfer by wafer bonding from a transfer wafer to a receiving substrate. One such implementation is “direct bonding” involving one bonding step of an array of devices from a transfer wafer to a receiving substrate, followed by removal of the transfer wafer. Another such implementation is “indirect bonding” which involves two bonding/de-bonding steps. In indirect bonding, a transfer head may pick up an array of devices from a donor substrate, and then bond the array of devices to a receiving substrate, followed by removal of the transfer head.

### SUMMARY

One of the important issues that may influence the quality of transferring is the very instant that the devices are in contact with the receiving wafer. According to some embodiments of the present disclosure, an electrical binding structure is provided. The electrical binding structure includes a substrate, a contact pad set, and a combination of a micro device and an electrode set. The contact pad set is on the substrate in which the contact pad set includes at least one contact pad, and the at least one contact pad is conductive. The combination of the micro device and the electrode set is on the contact pad set. The electrode set includes at least one electrode. Opposite sides of the electrode set are respectively in contact with the micro device and the contact pad set. A vertical projection of a contact periphery between the contact pad set and the electrode set projected on the substrate is longer than a vertical projection of an outer periphery of the micro device projected on the substrate in which said vertical projection of the contact periphery projected on the substrate is enclosed by said vertical projection of the outer periphery projected on the substrate.

According to some embodiments of the present disclosure, a method of forming an electrical binding structure is provided. The method includes: forming a contact pad set on a substrate in which the contact pad set includes at least one contact pad, and the at least one contact pad is conductive; placing a combination of a micro device and an electrode set on the contact pad set such that opposite sides of the electrode set are respectively in contact with the micro device and the contact pad set, the electrode set including at least one electrode, a vertical projection of a contact periphery between the contact pad set and the electrode set projected on the substrate being longer than a vertical projection of an outer periphery of the micro device projected on the substrate, and said vertical projection of the contact periphery projected on the substrate being enclosed by said vertical projection of the outer periphery of the micro device projected on the substrate; forming a liquid layer between the electrode set and the contact pad set such that the micro device is gripped by a capillary force produced by the liquid layer; and evaporating the liquid layer such that the electrode set is bound to the contact pad set and is in electrical contact with the contact pad set.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is a schematic cross-sectional view of an electrical binding structure according to some embodiments of the present disclosure;

FIG. 1B is a perspective view of the electrical binding structure according to some embodiments of the present disclosure;

FIG. 1C is a bottom view of a top contact surface of a contact pad set according to some embodiments of the present disclosure;

FIG. 1D is a bottom view of a bottom contact surface of an electrode set according to some embodiments of the present disclosure;

FIG. 1E is a bottom view of the contact pad set and the electrode set when the electrode set is in proximity to or in contact with the contact pad set according to some embodiments of the present disclosure;

FIG. 1F is a schematic view of a contact periphery according to some embodiments of the present disclosure;

FIG. 1G is a schematic view of a primitive contact periphery according to some embodiments of the present disclosure;

FIG. 1H is a schematic perspective view illustrating a liquid layer in contact with the electrode set and the contact pad set according to some embodiments of the present disclosure;

FIG. 2 is a bottom view of the contact pad set and the electrode set when the electrode set is in proximity to or in contact with the contact pad set according to some embodiments of the present disclosure;

FIG. 3A is a bottom view of the contact pad set and the electrode set when the electrode set is in proximity to or in contact with the contact pad set according to some embodiments of the present disclosure;

FIG. 3B is a bottom view of the contact pad set and the electrode set when the electrode set is in proximity to or in contact with the contact pad set according to some embodiments of the present disclosure;

FIG. 4 is a top view of the contact pad set and the electrode set when the electrode set is in proximity to or in contact with the contact pad set according to some embodiments of the present disclosure;

FIG. 5A is a cross-sectional view of one type of a contact pad set and an electrode set according to some embodiments of the present disclosure;

FIG. 5B is a cross-sectional view of one type of a contact pad set and an electrode set according to some embodiments of the present disclosure;

FIG. 5C is a cross-sectional view of one type of a contact pad set and an electrode set according to some embodiments of the present disclosure;

FIG. 6A is a schematic cross-sectional view of an electrical binding structure according to some embodiments of the present disclosure;

FIG. 6B is a schematic bottom view of the contact pad set and the electrode set when the electrode set is in proximity to or in contact with the contact pad set according to some embodiments of the present disclosure;

FIG. 7 is a schematic bottom view of a contact pad set and an electrode set when the electrode set is in proximity to or in contact with the contact pad set according to some embodiments of the present disclosure;

FIG. 8 is a flow chart of a method of forming the electrical binding structure according to some embodiments of the present disclosure;

FIG. 9A is schematic cross-sectional views of intermediate stages of the method of forming the electrical binding structure according to some embodiments of the present disclosure;

FIG. 9B is schematic cross-sectional views of intermediate stages of the method of forming the electrical binding structure according to some embodiments of the present disclosure;

FIG. 9C is schematic cross-sectional views of intermediate stages of the method of forming the electrical binding structure according to some embodiments of the present disclosure; and

FIG. 9D is schematic cross-sectional views of intermediate stages of the method of forming the electrical binding structure according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the present disclosure. In other instances, well-known semiconductor processes and manufacturing techniques have not been described in particular detail in order to not unnecessarily obscure the present disclosure. Reference throughout this specification to “one embodiment,” “an embodiment” or the like means that a particular feature, structure, configuration, or characteristic described in contact with the embodiment is included in at least one embodiment of the disclosure. Thus, the appearances of the phrase “in one embodiment,” “in an embodiment” or the like in various places throughout this specification are not necessarily referring to the same embodiment of the disclosure. Furthermore, the particular features, structures, configurations, or characteristics may be combined in any suitable manner in one or more embodiments.

The terms “over,” “to,” “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

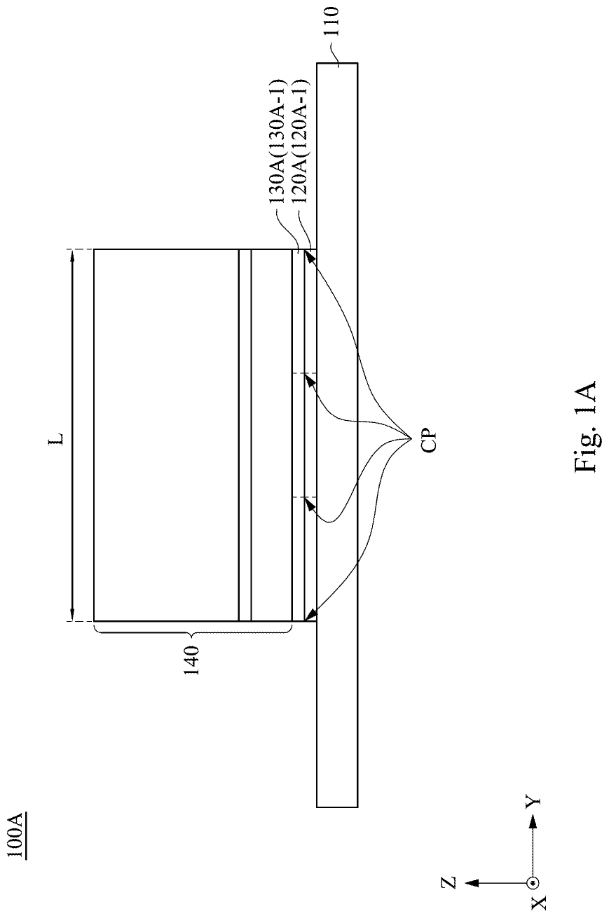

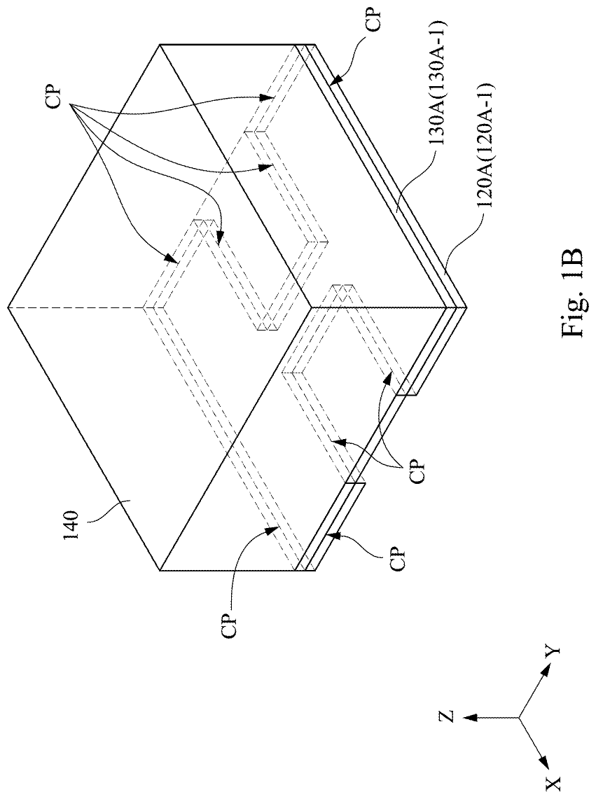

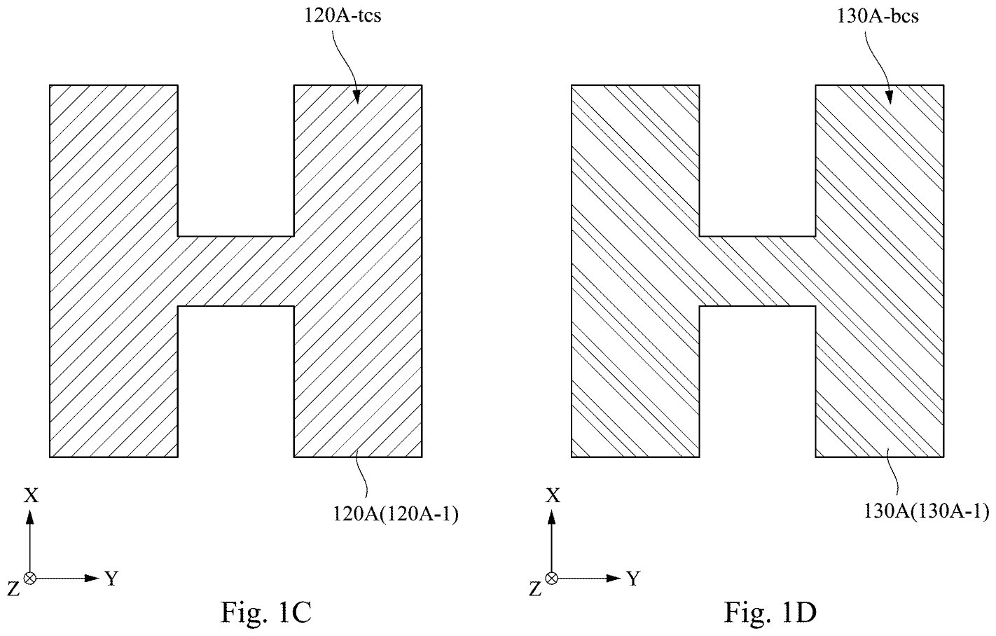

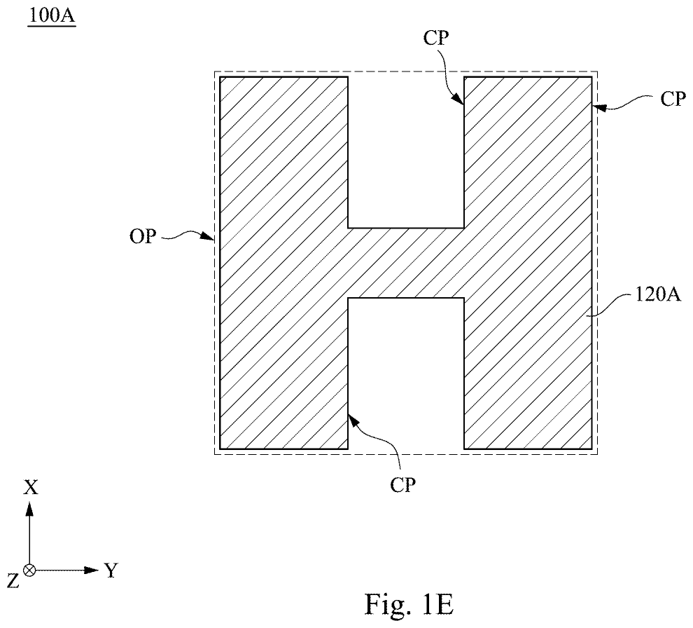

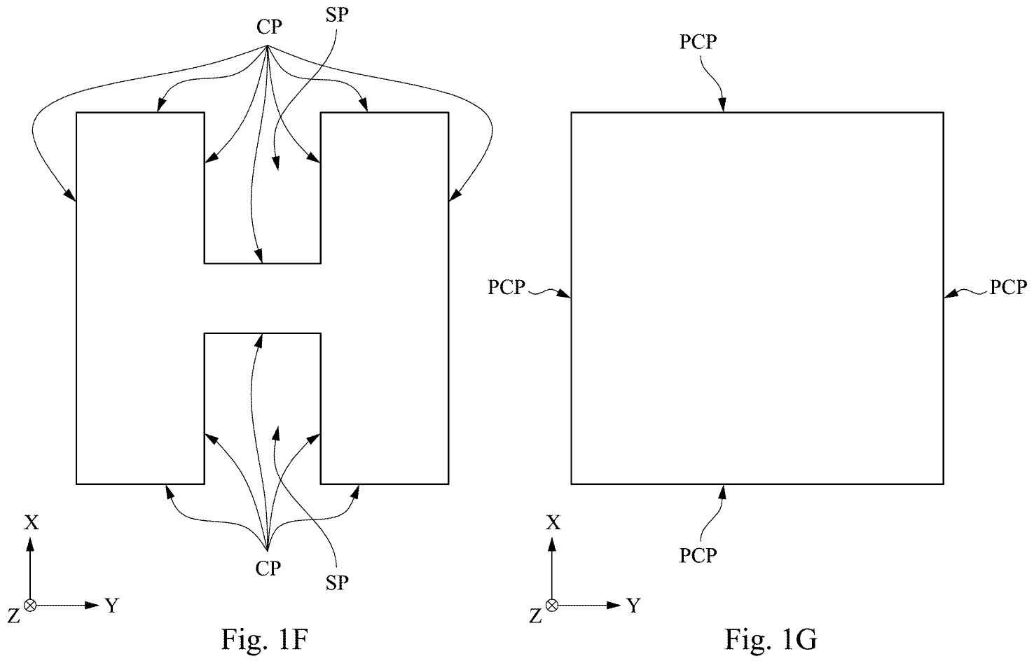

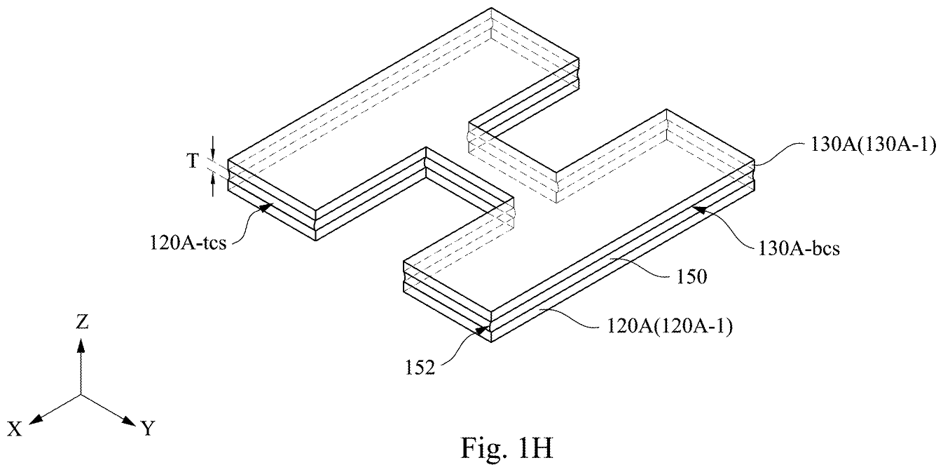

Reference is made to FIGS. 1A to 1E. FIG. 1A is a schematic cross-sectional view of an electrical binding structure 100A according to some embodiments of the present disclosure. FIG. 1B is a perspective view of the electrical binding structure 100A according to some embodiments of the present disclosure. FIG. 1B provides a three-dimensional view that makes the structural features of the electrical binding structure 100A easier to be understood. FIG. 1C is a bottom view of a top contact surface 120A-tcs of the contact pad set 120A according to some embodiments of the present disclosure. FIG. 1D is a bottom view of a bottom contact surface 130A-bcs of the electrode set 130A according to some embodiments of the present disclosure. FIG. 1E is a bottom view of the contact pad set 120A when the electrode set 130A is in proximity to or in contact with the contact pad set 120A according to some embodiments of the present disclosure. Note that a reference number of the electrode set 130A is absent in FIG. 1E because the electrode set 130A coincides (or is completely overlapped with) the contact pad set 120A from the bottom view. The electrical binding structure 100A includes a substrate 110, a contact pad set 120A, and a combination of a micro device 140 and an electrode set 130A. The contact pad set 120A is on the substrate 110 in which the contact pad set 120A includes at least one contact pad 120A-1, and the contact pad 120A-1 is conductive. In some embodiments, a thickness of the contact pad set 120A is smaller than or equal to about 2 μm, and preferably smaller than or equal to about 0.5 μm. The combination of the micro device 140 and the electrode set 130A is on the contact pad set 120A. The electrode set 130A includes at least one electrode 130A-1. In some embodiments, a thickness of the electrode set 130A ranges from about 0.2 μm to about 2 μm, and preferably ranges from about 0.3 μm to about 1 μm. Opposite sides of the electrode set 130A are respectively in contact with the micro device 140 and the contact pad set 120A. A vertical projection of a contact periphery CP (of the contact area) between the contact pad set 120A and the electrode set 130A projected on the substrate 110 is longer than a vertical projection of an outer periphery OP of the micro device 140 projected on the substrate 110. The vertical projection of the contact periphery CP projected on the substrate 110 is enclosed by the vertical projection of the outer periphery OP of the micro device 140 projected on the substrate 110.

FIG. 1F is a schematic view of a contact periphery CP according to some embodiments of the present disclosure. FIG. 1G is a schematic view of a primitive contact periphery PCP according to some embodiments of the present disclosure. FIG. 1H is a schematic perspective view illustrating a liquid layer 150 respectively in contact with the electrode set 130A and the contact pad set 120A according to some embodiments of the present disclosure. In some embodiments, due to purposely designed shapes of the contact pad set 120A (e.g., a shape of “H” as exemplified in FIG. 1C) and the electrode set 130A (e.g., a shape of “H” as exemplified in FIG. 1D), when the contact pad set 120A and the electrode set 130A are brought into proximity to the liquid layer 150 (e.g., a water layer) therebetween and opposite sides of the liquid layer 150 are respectively in contact with the contact pad set 120A and the electrode set 130A, a total length of the contact periphery CP (as referred to FIG. 1F) is greater than a total length of a primitive contact periphery PCP in which the shape of the contact pad set 120A and the shape of the electrode set 130A are not purposely designed (as referred to FIG. 1G). FIG. 1F may also be helpful in understanding the embodiments as mentioned. Those purposely designed shapes are designed to increase a total length of a contact periphery CP between the contact pad set 120A and the electrode set 130A. Taking embodiments illustrated by FIGS. 1C and 1D as an example, when the shape of the contact pad set 120A and the shape of the electrode set 130A are “H”, the contact periphery CP is greater than the primitive contact periphery PCP in which both the shape of the contact pad set 120A and the shape of the electrode set 130A are square. Note that the comparison is made with a presumption if sunken portions SP (as labeled in FIG. 1F) of “H” are refilled, a total area will be the same as a total area of the square as shown in FIG. 1G.

Perspective (three-dimensional) views that illustrate the embodiments mentioned above is shown in FIGS. 1B and 1H. In some embodiments, the electrode set 130A and the contact pad set 120A may be brought into proximity to each other and in contact with the liquid layer 150 therebetween, such that the combination of the electrode set 130A and the micro device 140 thereon is gripped by a capillary force produced by the liquid layer 150 (e.g., referred to FIG. 1H in which meniscuses 152 of the liquid layer 150 are formed due to the capillary force). After that, the liquid layer 150 is evaporated such that the electrode set 130A is stuck and bound to the contact pad set 120A. In these embodiments, since the contact pad set 120A and the electrode set 130A are designed in the shape of “H”, said capillary force is greater than the case when both of the electrode set 130A and the contact pad set 120A are designed in the shape of square. The greater capillary force is of great help in a quality of binding and the subsequent bonding between the electrode set 130A and the contact pad set 120A since the capillary force can assist in fixing the electrode set 130A within a controllable region when the electrode set 130A is attached to the liquid layer 150. Furthermore, the capillary force can assist a formation of binding (and also a formation of bonding) between the electrode set 130A and the contact pad set 120A during and after the evaporation of the liquid layer 150. Said binding is a special phenomenon found in these kinds of liquid layer 150 assisted gripping and contact. The bonding is a phenomenon when two objects (usually metals) are in contact and atoms are diffused between the two objects. In some embodiments, a lateral length L of the micro device is less than or equal to about 100 μm. The restriction of the lateral length L is to ensure that the capillary force significantly helps and dominates the binding between the electrode set 130A and the contact pad set 120A.

It is noted that the contact periphery CP and the primitive contact periphery PCP as mentioned can be interpreted as a contact periphery (or a plurality of discrete contact peripheries, as will be mentioned in some embodiments later) when the electrode set 130A is in contact with the contact pad set 120A. They can also be interpreted as a contact periphery (or contact peripheries) when the liquid layer 150 is between and in contact with the electrode set 130A and the contact pad set 120A. In this case, the contact periphery CP (and the primitive contact periphery PCP) is regarded as a periphery having a thickness T (as shown in FIG. 1H) measured from a bottom surface 130A-bcs of the electrode set 130A to a top surface 120A-tcs of the contact pad set 120A through a periphery of the liquid layer 150.

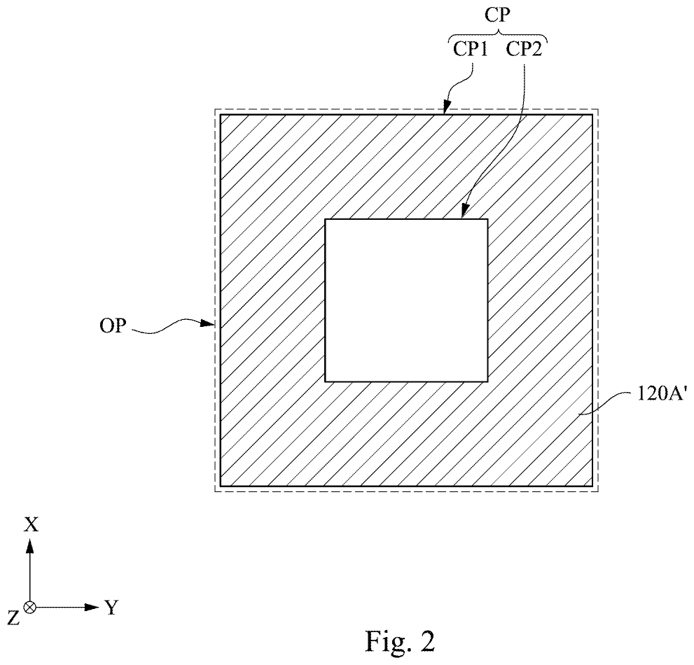

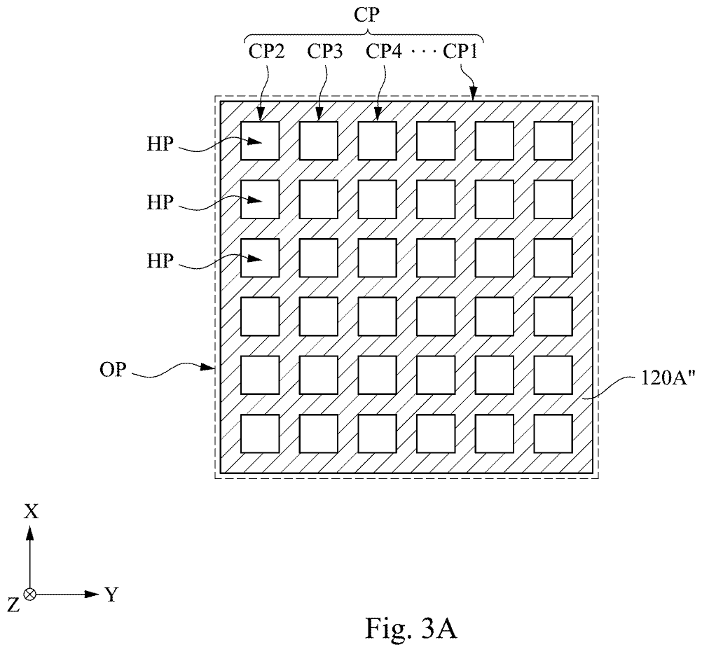

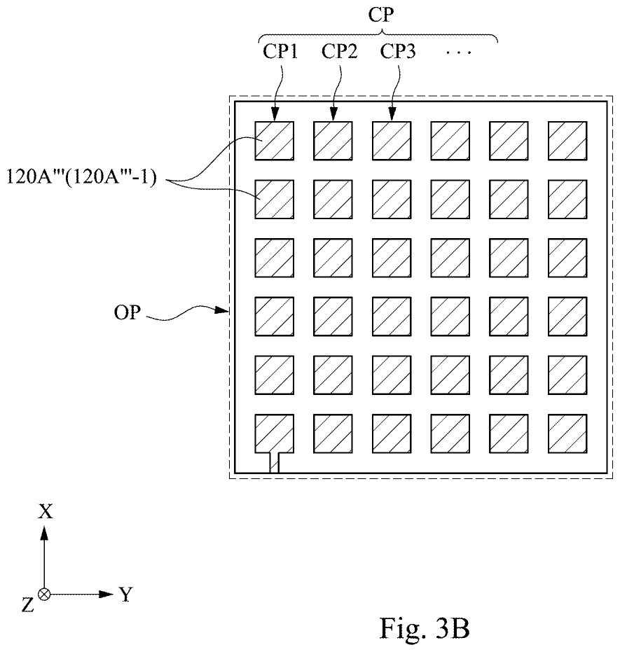

Reference is made to FIGS. 2 to 3B. FIG. 2 is a bottom view of the contact pad set 120A′ and the electrode set 130A′ (not explicitly shown because it is overlapped with and behind the contact pad set 120A′ in FIG. 2) when the electrode set 130A′ is in proximity to or in contact with the contact pad set 120A′ according to some embodiments of the present disclosure. FIG. 3A is a bottom view of the contact pad set 120A″ and the electrode set 130A″ (not explicitly shown because it is overlapped with and behind the contact pad set 120A″ in FIG. 3A) when the electrode set 130A″ is in proximity to or in contact with the contact pad set 120A″ according to some embodiments of the present disclosure. FIG. 3B is a bottom view of the contact pad set 120A′″ and the electrode set 130A′″ (not explicitly shown because it is overlapped with and behind the contact pad set 120A′″ in FIG. 3B) when the electrode set 130A′″ is in proximity to or in contact with the contact pad set 120A′″ according to some embodiments of the present disclosure. The contact pad set 120A′″ includes a plurality of contact pads 120A′″-1, and the electrode set 130A′″ includes a plurality of electrodes 130A′″-1 (not explicitly shown because it is overlapped with and behind the contact pads 120A′″-1 in FIG. 3B). Note that labels of electrode sets 130A′, 130A″ and 130A′″ are absent from FIGS. 2 to 3B because the electrode sets 130A′, 130A″ and 130A′″ respectively coincide (or are completely overlapped with) the contact pad sets 120A′, 120A″, and 120A′″ from the bottom views. Note that FIG. 1A can also be interpreted by FIG. 2 because FIG. 1A is a cross-sectional view. In the embodiments as illustrated by FIG. 2, the contact pad set 120A′ and the electrode set 130A′ are hollowed such that the contact periphery CP is consisted of a first contact periphery CP1 and a second contact periphery CP2 (i.e., CP=CP1+CP2) which are discrete from each other. All of the contact peripheries will be labeled only by “CP” for simplicity even though there are different shapes of contact peripheries in different embodiments of the present disclosure. Technical effects of the embodiments as illustrated by FIG. 2 is similar to the technical effects of the embodiments as shown in FIGS. 1C to 1E, and will not be described in details again.

Embodiments as illustrated by FIG. 3A can be regarded as a modification from the embodiments as illustrated by FIG. 2. The contact pad set 120A″ and the electrode set 130A″ of the embodiments as illustrated by FIG. 3A has a plurality of discrete hollowed portions HP. FIG. 3B illustrates embodiments that a plurality of contact pads 120A′″-1 and a plurality of electrode pads 130A′″-1 (again, not explicitly shown because of the “coincide”) form a plurality of contact peripheries CP1, CP2, CP3 . . . etc. The contact periphery CP is a sum of said plurality of the contact peripheries CP1, CP2, CP3 . . . etc,. Note that one of the contact pads 120PC-1 is connected to outside and is electrically connected to an applied voltage (not shown).

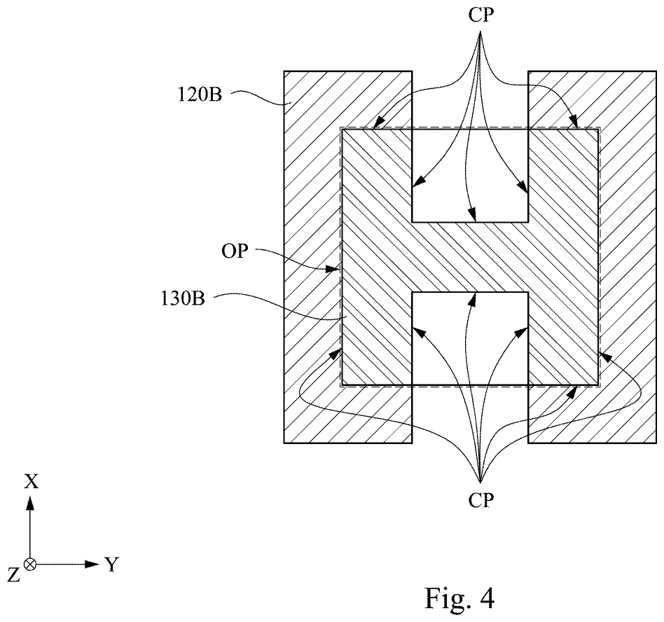

FIG. 4 is a top view of the contact pad set 120B and the electrode set 130B when the electrode set 130B is in proximity to or in contact with the contact pad set 120B according to some embodiments of the present disclosure. In these embodiments, a size (or a lateral length L) of the micro device 140 is smaller than the contact pad set 120B.

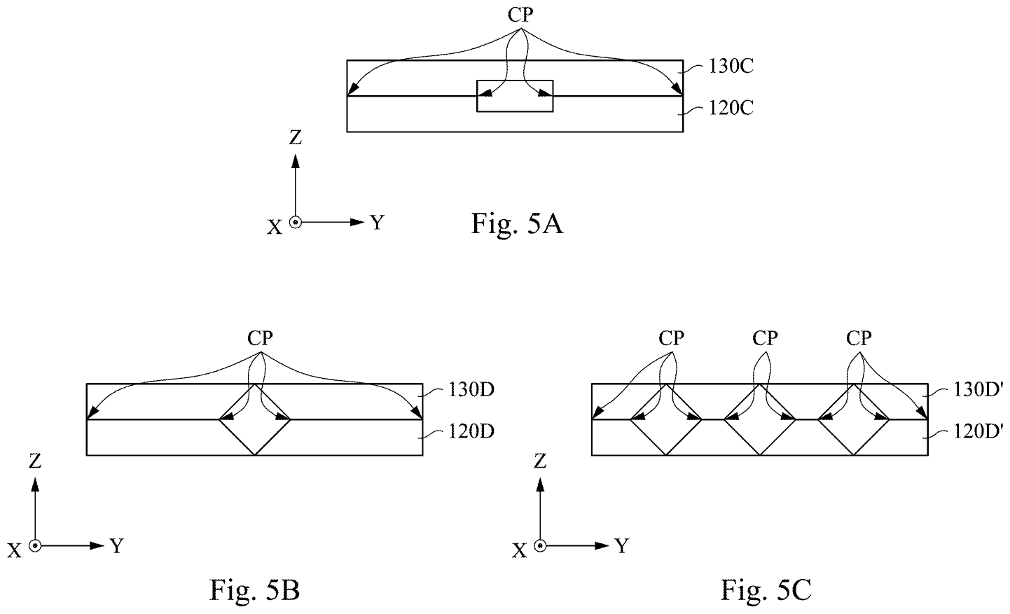

Reference is made to FIGS. 5A to 5C. FIGS. 5A to 5C respectively are cross-sectional views of three different types of contact pad sets and electrode sets according to some embodiments of the present disclosure. In these embodiments a vertical projection of at least one contact peripheries CP projected on the substrate 110 is crossed over by a vertical projection of the contact pad sets 120C, 120D, 120D′ projected on the substrate 110 and/or a vertical projection of the electrode sets 130c, 130D, 130D′ projected on the substrate 110.

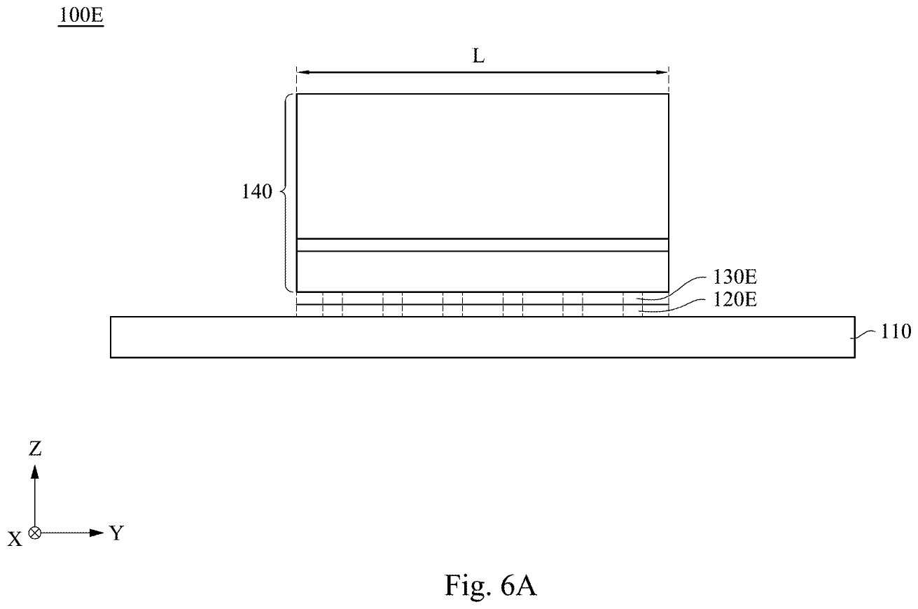

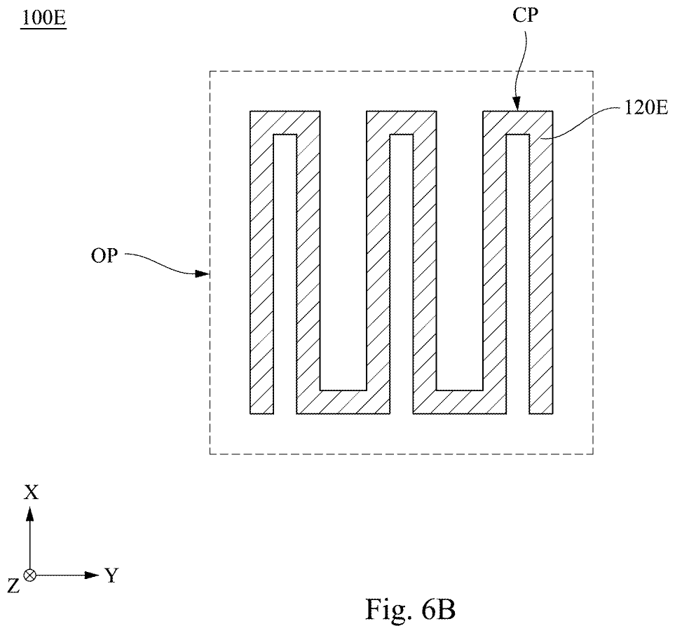

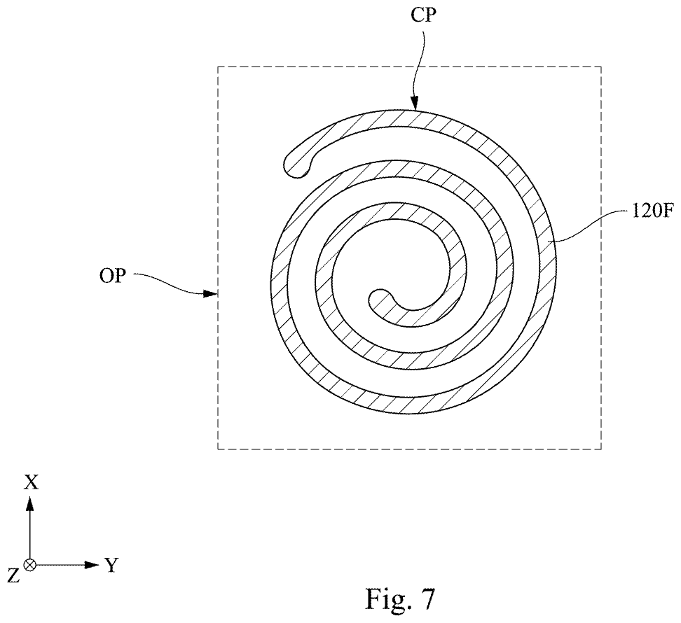

Reference is made to FIGS. 6A, 6B, and 7. FIG. 6A is a schematic cross-sectional view of an electrical binding structure 100E according to some embodiments of the present disclosure. FIG. 6B is a schematic bottom view of the contact pad set 120E and the electrode set 130E (again, not explicitly labeled due to said “coincide”) when the electrode set 130E is in proximity to or in contact with the contact pad set 120E according to some embodiments of the present disclosure. FIG. 7 is a schematic bottom view of a contact pad set 120F and an electrode set 130F (again, not explicitly labeled due to said “coincide”) when the electrode set 130F is in proximity to or in contact with the contact pad set 120F according to some embodiments of the present disclosure. FIGS. 6A and 6B illustrating embodiments in which the contact pad set 120E and the electrode set 130E are with a shape of zigzag (or similar to zigzag). FIG. 7 illustrating embodiments in which the contact pad set 120F and the electrode set 130F are with a spiral shape. The above embodiments demonstrate some other possible structural features which obey all the limitations as mentioned above and also capable of increasing said capillary force.

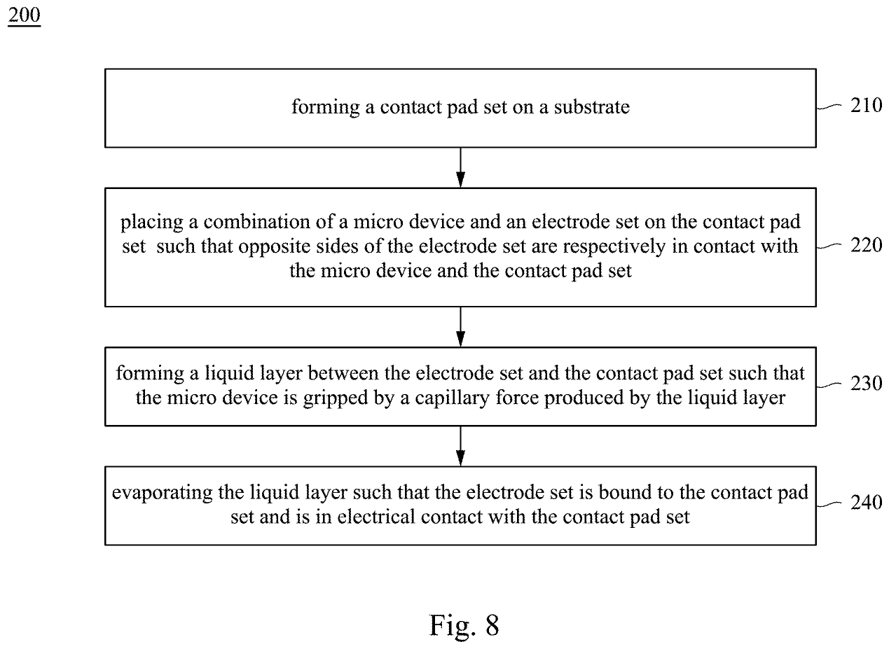

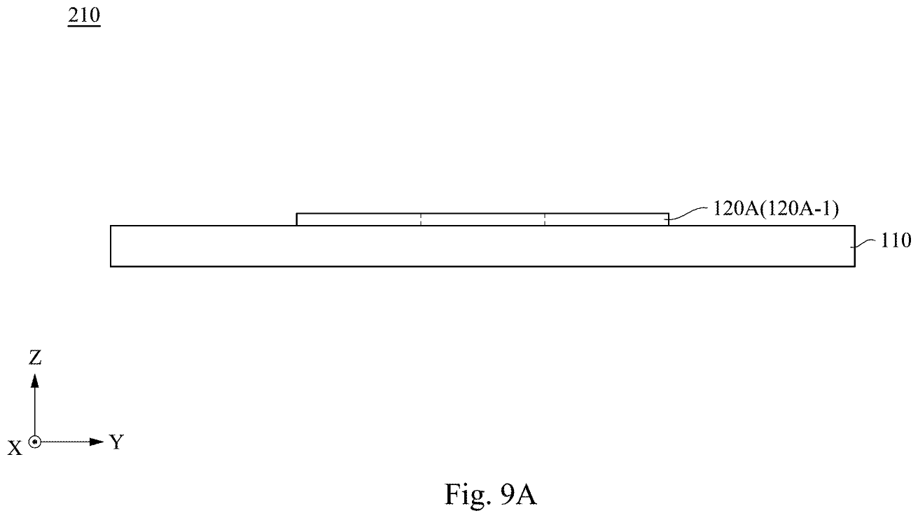

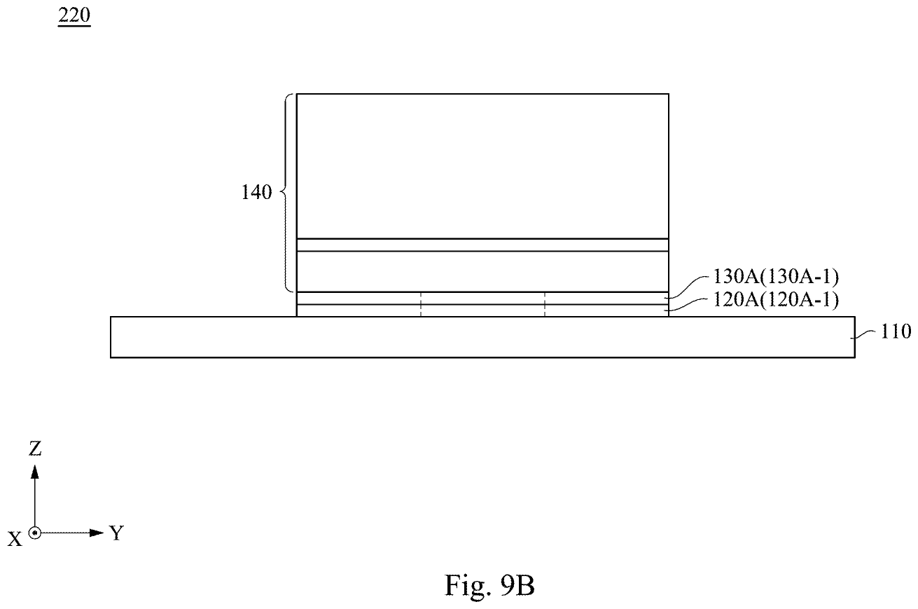

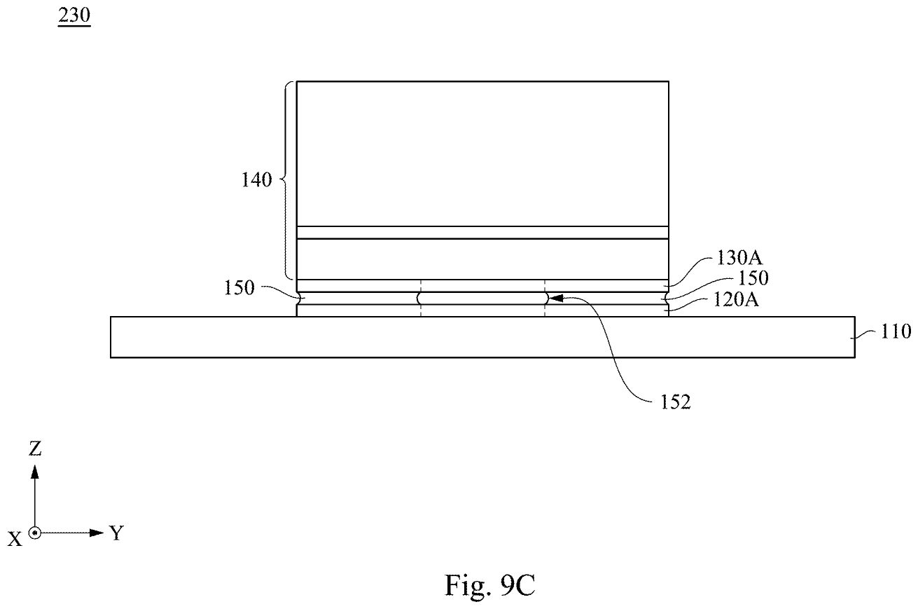

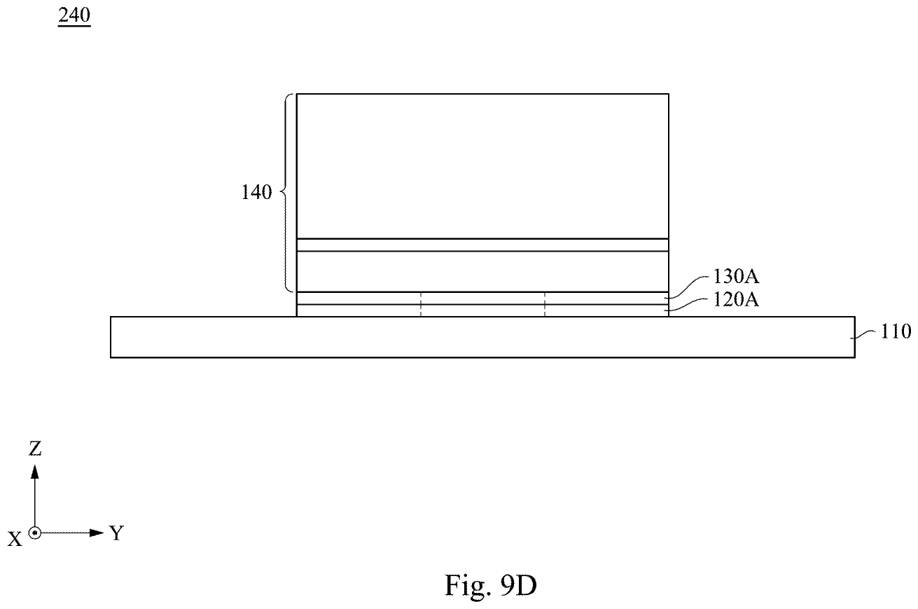

FIG. 8 is a flow chart of a method 200 of forming the electrical binding structure 100A according to some embodiments of the present disclosure. FIGS. 9A to 9D are schematic cross-sectional views of intermediate stages of the method 200 of FIG. 8 according to some embodiments of the present disclosure. References are made to FIGS. 8 to 9D. The method 200 begins with operation 210 in which a contact pad set 120A is formed on the substrate 110 in which the contact pad set 120A includes at least one contact pad 120A-1, and the contact pad 120A-1 is conductive (as referred to FIG. 9A). In some embodiments, an adhesive layer (not shown in figures) is formed on the substrate 110 before the contact pad set 120A is formed. The method 200 continues with operation 220 in which a combination of a micro device 140 and an electrode set 130A is placed on the contact pad set 120A such that opposite sides of the electrode set 130A are respectively in contact with the micro device 140 and the contact pad set 120A. The electrode set 130A includes at least one electrode 130A-1. A vertical projection of a contact periphery CP between the contact pad set 120A and the electrode set 130A projected on the substrate 110 is longer than a vertical projection of an outer periphery OP of the micro device 140 projected on the substrate 110, and said vertical projection of the contact periphery CP projected on the substrate being enclosed by said vertical projection of the outer periphery of the micro device 140 on the substrate (as referred to FIG. 9B).

The method 200 continues with operation 230 in which a liquid layer 150 is formed between the electrode set 130A and the contact pad set 120A such that the micro device 140 is gripped by a capillary force produced by the liquid layer 150 (as referred to FIG. 9C). In some embodiments, the liquid layer 150 includes water. It is noted that operation 220 and operation 230 can be exchanged. In some other embodiments, the liquid layer 150 is formed on the contact pad set 120A, then the combination of the electrode set 130A and the micro device 140 is placed over the contact pad set 120A such that the electrode set 130A is in contact with the liquid layer 150 and is gripped by a capillary force produced by the liquid layer 150. In some embodiments, the liquid layer 150 can be formed by lowering a temperature of the contact pad set 120A in an environment including a vapor such that at least a portion of the vapor is condensed to form the liquid layer 150. In some embodiments, the liquid layer 150 is formed at a temperature about the dew point. In some embodiments, the liquid layer 150 can be formed by showering a vapor on the substrate 110 such that at least a portion of the gas is condensed to form the liquid layer 150. In some embodiments, the gas has a water vapor pressure higher than an ambient water vapor pressure. The gas consists essentially of nitrogen and water. In some embodiments, a thickness of the liquid layer 150 between the electrode set 130A and the contact pad set 120A is smaller than a thickness of the micro device 140 when the micro device 140 is gripped by the capillary force produced by the liquid layer 150.

The method 200 continues with operation 240 in which the liquid layer 150 is evaporated such that the electrode set 130A is stuck to and bound to the contact pad set 120A and is in electrical contact with the contact pad set 120A (as referred to FIG. 9D). In some embodiments, the liquid layer 150 is evaporated by raising a temperature of the contact pad set 120A. In some embodiments, one of the contact pad set 120A and the electrode set 130A includes a bonding material, and the temperature of the conductive pad set 120A can be further raised to a temperature point to bond the electrode set 130A to the contact pad set 120A. The temperature point can be above the melting point of the bonding material, below the melting point of the bonding material and above a boiling point of the liquid layer 150, or above a eutectic point of the contact pad set 120A and the electrode set 130A. In some embodiments, a thickness of the bonding material ranges from about 0.2 μm to about 2 μm. In some embodiments, a preferred thickness of the bonding material ranges from about 0.3 μm to about 1 μm. One of the contact pad set 120A and the electrode set 130A may include one of copper and copper rich material. The bonding material may be a tin rich, an indium rich, or a titanium rich material. The “rich” herein means accounting for more than half of total number of atoms.

In summary, an electrical binding structure and a method of forming the same are provided to help a liquid layer between an electrode set and a contact pad set to grip the electrode set and to bind the electrode set to the contact pad set. The electrical binding structure can make a contact periphery greater than a primitive contact periphery as mentioned in the description, so as to enhance a capillary force produced by the liquid layer which is used to grip the electrode.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

1. An electrical binding structure, comprising:
a substrate;
a contact pad set on the substrate, wherein the contact pad set comprises at least one contact pad wherein the contact pad is conductive; and
a combination of a micro device and an electrode set on the contact pad set, the electrode set comprising at least one electrode, opposite sides of the electrode set being respectively in contact with the micro device and the contact pad set, a vertical projection of a contact periphery between the contact pad set and the electrode set projected on the substrate being longer than a vertical projection of an outer periphery of the micro device projected on the substrate, wherein said vertical projection of the contact periphery projected on the substrate is enclosed by said vertical projection of the outer periphery projected on the substrate.

2. The electrical binding structure of claim 1, further comprising an adhesive layer between the contact pad set and the substrate.

3. The electrical binding structure of claim 1, wherein one of the contact pad set and the electrode set comprises one of copper, tin, titanium, and indium.

4. The electrical binding structure of claim 1, wherein a lateral length of the micro device is less than or equal to about 100 μm.

5. A method of forming an electrical binding structure, comprising:
forming a contact pad set on a substrate, wherein the contact pad set comprises at least one contact pad, and the at least one contact pad is conductive;
placing a combination of a micro device and an electrode set on the contact pad set such that opposite sides of the electrode set are respectively in contact with the micro device and the contact pad set, the electrode set comprising at least one electrode, a vertical projection of a contact periphery between the contact pad set and the electrode set on the substrate being longer than a vertical projection of an outer periphery of the micro device on the substrate, and said vertical projection of the contact periphery projected on the substrate being enclosed by said vertical projection of the outer periphery of the micro device projected on the substrate;
forming a liquid layer between the electrode set and the contact pad set such that the micro device is gripped by a capillary force produced by the liquid layer; and
evaporating the liquid layer such that the electrode set is bound to the contact pad set and is in electrical contact with the contact pad set.

6. The method of claim 5, wherein forming the liquid layer comprises:
lowering a temperature of the contact pad set in an environment comprising a vapor such that at least a portion of the vapor is condensed to form the liquid layer.

7. The method of claim 5, wherein forming the liquid layer comprises:
showering a vapor on the substrate such that at least a portion of the vapor is condensed to form the liquid layer.

8. The method of claim 7, wherein the vapor has a water vapor pressure higher than an ambient water vapor pressure.

9. The method of claim 7, wherein the vapor consists essentially of nitrogen and water.

10. The method of claim 5, further comprising forming an adhesive layer on the substrate before forming the contact pad set.

11. The method of claim 5, wherein the liquid layer comprises water.

12. The method of claim 6, wherein the liquid layer is formed at a temperature about the dew point.

13. The method of claim 5, wherein evaporating the liquid layer comprises:
raising a temperature of the contact pad set such that the electrode set is stuck to the contact pad set after the liquid layer is evaporated.

14. The method of claim 5, wherein at least one of the contact pad set and the electrode set comprises a bonding material, and the method further comprises:
raising a temperature of the contact pad set to be above a melting point of the bonding material after evaporating the liquid layer.

15. The method of claim 5, wherein at least one of the contact pad set and the electrode set comprises a bonding material, and the method further comprises:
raising a temperature of the contact pad set to be below a melting point of the bonding material and above a boiling point of the liquid layer after evaporating the liquid layer.

16. The method of claim 5, further comprising:
raising a temperature of the contact pad set to be above a eutectic point of the contact pad set and the electrode set after evaporating the liquid layer.

17. The method of claim 5, wherein a thickness of the liquid layer between the electrode set and the contact pad set is less than a thickness of the micro device when the micro device is gripped by the capillary force.

18. The method of claim 5, wherein one of the contact pad set and the electrode set comprises one of copper, tin, titanium, and indium.

19. The method of claim 5, wherein a lateral length of the micro device is less than or equal to about 100 μm.
